(19) United States
(12) Patent Application Publication
(10) Pub. No.: US 2010/0203263 A1
(43) Pub. Date: Aug. 12, 2010

(54) Deposition of Chalcogenide Materials via Vaporization Process

(76) Inventor: Wolodymyr Czubatyj, Warren, MI (US)

Correspondence Address: Kavin L. Bray;OVONYX, INC., 2956 Waterview Drive, Rochester Hills, MI, 48309, US

(21) Appl. No.: 12/369,807

(22) Filed: Feb. 12, 2009

(51) Int. Cl. C23C 16/44; B05D 5/12; B05D 7/22

(52) U.S. Cl. 427/596; 427/58; 427/105

(57) ABSTRACT

A method of depositing a chalcogenide material. The method includes vaporizing a condensed phase chalcogenide source material and forming a product chalcogenide material on a remote deposition surface by condensing the vapor. Vaporization may occur via sublimation or evaporation and the condensed phase chalcogenide source material may be a solid-phase source material or a liquid-phase source material. The deposition surface may include a patterned feature such as a hole, trench or other opening and the method provides for conformal or nearly conformal filling of the feature. The composition of the product chalcogenide material closely corresponds to the composition of the chalcogenide source material.

### FIELD OF INVENTION

This invention relates to the deposition of chalcogenide materials. More particularly, this invention relates to a method of depositing chalcogenide materials from a solid source via a thermal process. Most particularly, this invention relates to a method of depositing chalcogenide materials conformally via condensation from a vapor phase ambient formed from a solid source.

### BACKGROUND OF THE INVENTION

Chalcogenide materials are materials that contain a chalcogen element (S, Se, Te) and typically one or more additional elements that serve to modify electronic or structural properties. The II-VI semiconductors (e.g. CdS, ZnTe etc.) are a well-known class of chalcogenide materials. These materials have been widely investigated for their electronic bandgap properties and their potential for providing short wavelength light emission for LED and laser applications.

Another important class of chalcogenide materials includes the chalcogenide compositions that are currently being developed for memory and electrical switching applications. The chalcogenide memory materials are typically chalcogenide phase-change materials and can be used in optical and electrical memory applications. A phase change material is a material that is capable of undergoing a transformation, preferably reversible, between two or more distinct structural states. The distinct structural states may be distinguished on the basis of, for example, crystal structure, atomic arrangement, order or disorder, fractional crystallinity, relative proportions of two or more different structural states, or a physical (e.g. electrical, optical, magnetic, mechanical) or chemical property.

The active recording materials in many optical storage technologies are chalcogenide phase-change materials that are reversibly transformable between a crystalline state and an amorphous state through the application of optical energy. These materials can be used to store information by defining a series of two or more distinct structural states, each of which is defined by a characteristic proportion of crystalline and amorphous phase domains within a given volume, and associating a unique information value to each structural state. Storage of data occurs by applying optical energy to the chalcogenide phase-change material in an amount necessary to convert the material to the structural state associated with the input data.

The optical phase change chalcogenide materials are reversibly transformable between different structural states through the controlled application of energy. The proportion of amorphous phase can be increased by applying energy sufficient to create a local temperature in the phase change material that exceeds the melting temperature and removing the energy at a rate sufficient to prevent crystallization upon cooling. The proportion of crystalline phase can be increased by applying energy sufficient to create a local temperature in the phase change material that exceeds the crystallization temperature so that a controlled transformation of amorphous phase material to crystalline phase material is induced. Reading of the information content of the phase change material occurs through the detection of a physical characteristic of the structural state of the material. In optical recording, for example, reflectivity is a widely used as a parameter for detecting the structural state. The reflectivity difference between the crystalline and amorphous states provides sufficient contrast to permit clear resolution of structural states that differ with respect to the relative proportions of crystalline and amorphous phase volume fractions.

Two other important types of chalcogenide materials are the electrical memory and electrical switching materials. In the electrical memory materials, application of electrical energy induces changes in the structural state of a chalcogenide phase-change material. The relative volume fraction of crystalline and amorphous phase domains can be continuously varied by controlling the duration and magnitude of a series of one or more applied electrical current or voltage pulses. As in the optical memory materials, each structural state has a unique resistance and each resistance value can be associated with a unique information value. By applying an appropriate electrical pulse, the electrical chalcogenide memory material can be programmed into the resistance state that corresponds to a particular data value to write data to the material. The chalcogenide electrical memory materials can be reversibly transformed among their different resistance states to provide erasing and rewriting capabilities. Both the electrical and optical chalcogenide memory materials can be incorporated into arrays to provide advanced, high density memory capability.

The chalcogenide electrical switching materials are amorphous phase materials that do not undergo crystalline-amorphous phase transformations. Instead, these materials are switchable between a quiescent resistive state and a dynamic conductive state upon application of a voltage that exceeds a threshold voltage. In the resistive state, the materials inhibit the flow of electrical current and upon application of the thresholding voltage, the material switches nearly instantaneously to a dynamic state that includes a highly conductive filamentary portion that permits the flow of current through high mobility charge carriers believed to include lone pair electrons removed from valence orbitals of chalcogen elements.

As the appreciation of the capabilities of chalcogenide materials grows, greater attention is being placed on further understanding their properties and on developing new chalcogenide materials that exhibit a wider range of properties. The development of new materials requires the production of new compositions or the production of existing compositions in ways that impart unique microstructures. The primary production methods for the chalcogenide memory and switching materials are sputtering and physical vapor deposition. Although these techniques have provided many interesting and useful materials, it is expected that the development of new production methods will expand the range of compositions and properties of chalcogenide materials and will extend the practical application of chalcogenide materials.

In the fabrication of practical chalcogenide devices, it is desirable to reduce the length scale or feature size as much as possible so that a larger number of devices can be formed on a given substrate area. As the feature size of devices is minimized, however, processing of the devices becomes more difficult. Small scale features become more difficult to define as the lithographic limit of resolution is reached and features that are defined become more difficult to process.

A common step in device fabrication involves depositing a layer and forming an opening in it. Openings such as channels, trenches, holes, vias, pores or depressions in layers are commonly employed to permit interconnections between devices or layers of a structure. Typically, the opening is formed by lithography or etching and is subsequently filled with another material. As the dimension or length scale of the opening decreases, it becomes increasingly difficult to satisfactorily fill the opening with another material.

Techniques such as physical vapor deposition (PVD) or sputtering fail to provide dense or complete filling of openings when the dimensions of the opening are reduced below a critical size. Instead of providing a dense, uniform filling, these techniques increasingly incompletely fill openings as the lateral dimension of the opening decreases. The deposited layer has a tendency to include gaps, pores, or other unfilled regions. The packing density of material formed in the opening may vary in the depth or lateral dimensions of the opening.

Lack of structural uniformity in the filling of openings compromises device functionality as variations occur from device-to-device across an array of devices on a substrate. In addition, less than optimal performance is achieved for each device due to the defective nature of the deposited material. Imperfections in filling openings become especially pronounced as the aspect ratio (ratio of the dimension normal to the substrate to the dimension parallel to the substrate) of the opening increases. Deep, narrow channels, for example, are more difficult to uniformly fill than channels that are shallow and wide. With deep, narrow features, sputtering and other physical deposition techniques are oftentimes unable to deliver sufficient material to the bottom of the feature. Instead, a layer of material is formed over or only near the top of the feature and the lower part of the feature is blocked and remains partially unfilled.

Conformality of deposition is another processing difficulty that becomes exacerbated as feature size decreases. Fabrication of semiconductor devices generally involves forming a stack of layers, where the individual layers may differ in dimensions (lateral to or normal to the substrate) and compositions. The process of fabricating a thin film device generally involves sequential deposition of one layer upon a lower (previously formed) layer. Optimal device performance requires conformality of later-formed layers with earlier-formed layers. Each layer in a stack must conform to the shape and contours of the layer in the stack upon which it is formed. Smooth and uniform coverage is desired.

In addition to difficulties with achieving uniform filling, openings also present complications for achieving conformal deposition that become more pronounced as the lateral dimension of the opening decreases. The boundary or perimeter of an opening is frequently defined by an edge, step, or other relatively discontinuous feature. The shape of an opening is generally defined by a sidewall or perimeter boundary and a lower surface or bottom boundary. A trench opening, for example, is defined by generally vertical sidewalls and a bottom surface that is generally parallel to the substrate.

When fabricating thin film devices, it is often necessary to first form a layer with an opening and to subsequently deposit another layer over this layer. Conformality requires that the subsequent layer faithfully conform to the shape and texture of the underlying layer having the opening. The subsequent layer must deposit uniformly over both the portion of the underlying layer in which the opening has not been formed as well as over the opening itself. Conformality over the opening requires uniform coverage of the edges, steps, sidewalls, and bottom surfaces that form the boundaries of the opening. Achieving conformality over discontinuous features becomes increasingly difficult as the feature size of the opening decreases, or as the aspect ratio of the opening increases.

Fabrication of chalcogenide memory and switching devices often includes a step of forming an opening in a dielectric layer and filling the opening with a chalcogenide material. Miniaturization of chalcogenide memory and switching devices requires methods for conformally depositing chalcogenide materials into openings with small lateral dimensions and/or high aspect ratios. Preferably, the methods would enable the conformal fabrication of active chalcogenide materials in features having dimensions near, at or below the lithographic limit.

Chemical Vapor Deposition (CVD) is one method available in the prior art for filling openings that is expected to remain conformal as the feature size of the opening decreases. In the CVD process, precursors of the constituent elements of a material are reacted to produce a thin film on a substrate. The precursors are introduced into the reactor in gas phase form. Precursors that are in the gas phase at room conditions are directly introduced into the reactor, typically in diluted form via a carrier gas. Liquid and solid phase precursors are vaporized or sublimed and then introduced into the reactor, also typically in diluted form in the presence of a carrier gas. Upon introduction into the reactor, precursors containing the chemical constituents of the desired material are decomposed (thermally, photochemically, or in a plasma) to provide intermediate species of the constituents that subsequently react to form a thin film of desired composition. The rate of deposition, stoichiometry, composition and morphology of the film can be varied through appropriate control over process parameters such as reaction temperature; substrate; selection of precursor; reactor pressure; and the rate of introduction of precursors into the reactor. The molecular dimensions of the gas phase precursors used in CVD allow the precursors to enter small-dimensional openings, where they subsequently react to form a relatively uniform layer.

Although CVD in principle is a viable strategy for forming conformal thin film chalcogenide materials at lithographic or sublithographic dimensions, the technique suffers from the limited availability of suitable gas phase precursors for a variety of desired chalcogenide compositions. Many of the most effective chalcogenide compositions are multiple element (ternary and higher) compositions and it becomes difficult to simultaneously control the decomposition or reactivity of multiple precursors to provide uniform films of multi-element materials. Precursor development and qualification is an expensive endeavor. In addition, the purity of material deposited by CVD can be compromised by residual elements released from ligands of the precursors upon reaction or decomposition of the precursors. Also, the reaction conditions (e.g. high temperatures or plasma conditions) needed for reaction of the precursors may damage other layers in the device structure. There is a need, therefore, for alternative methods of forming chalcogenide materials in conformal fashion.

### SUMMARY OF THE INVENTION

This invention provides a method for forming thin film chalcogenide materials. The method includes condensing a thin film chalcogenide material from the vapor produced by vaporizing a condensed phase chalcogenide source. The condensed phase chalcogenide source may be a solid-phase chalcogenide source, molten-phase chalcogenide source or liquid-phase chalcogenide source. Vaporization may occur through sublimation or evaporation.

In one embodiment, a solid-phase chalcogenide source is heated to a temperature below its melting point and the source material sublimes to form a vapor phase. In another embodiment, a solid-phase chalcogenide source is heated to a temperature at or above its melting point to form a molten or liquid-phase chalcogenide source and the source material evaporates to form a vapor phase. Heating of the chalcogenide source may be achieved with a thermal, electrical, or optical energy source. The heating process may be continuous, pulsed or intermittent in time. In one embodiment, the vapor forms in a non-ionizing environment. In another embodiment, the vapor forms in a plasma-free environment.

The chalcogenide-containing vapor phase formed from the chalcogenide source is transported away from the source to a deposition surface and condenses to form a thin film chalcogenide material. The thin film chalcogenide material may form as a solid phase, molten phase or liquid phase on the deposition surface. If the thin film chalcogenide material forms as a molten phase or liquid phase, it is subsequently transformed to a solid phase.

In one embodiment, the temperature of the deposition surface is less than the temperature of the chalcogenide source. In another embodiment, the temperature of the deposition surface is less than the melting point of the chalcogenide source. In a further embodiment, the temperature of the deposition surface is less than the melting point of the deposited thin film chalcogenide material. In still another embodiment, the temperature of the deposition surface is less than the glass transition temperature of the deposited thin film chalcogenide material.

In one embodiment, the deposition surface is a planar surface. In another embodiment, the deposition surface includes a feature and the thin film chalcogenide material is formed within the feature. In another embodiment, the thin film chalcogenide material conformally forms within or fills the opening. The feature may be an opening, hole, via, trench, groove, recess, edge, step, or depression. The cross-sectional shape of the feature may include a portion that is round, curved, elliptical, bent, or rectilinear. The feature may have an aspect ratio between 0.25:1 and 5:1. In one embodiment, the feature has an aspect ratio of at least 1:1. In another embodiment, the feature has an aspect ratio of at least 2:1. In another embodiment, the feature has an aspect ratio of at least 3:1.

In one embodiment, the condensed product chalcogenide thin film material is formed as an amorphous phase material on the deposition surface. In one embodiment, the product forms in a non-ionizing environment. In another embodiment, the product forms in a plasma-free environment.

In one embodiment, the composition of the condensed chalcogenide thin film material is approximately the same as the composition of the chalcogenide source material. In another embodiment, the atomic concentration of the chalcogen element in the condensed chalcogenide thin film material is between 90% and 110% of the atomic concentration of the chalcogen element in the chalcogenide source material. In another embodiment, the atomic concentration of the chalcogen element and at least one other element in the condensed chalcogenide thin film material are both between 90% and 110% of their respective atomic concentrations in the chalcogenide source material. In another embodiment, the atomic concentration of the chalcogen element in the condensed chalcogenide thin film material is between 80% and 120% of the atomic concentration of the chalcogen element in the chalcogenide source material. In another embodiment, the atomic concentration of the chalcogen element and at least one other element in the condensed chalcogenide thin film material are both between 80% and 120% of their respective atomic concentrations in the chalcogenide source material.

In one embodiment, the chalcogenide thin film material is an optical phase change material that is reversibly transformable between a high reflectivity state and a low reflectivity state upon application of optical energy, where the high reflectivity and low reflectivity states differ in fractional crystallinity.

In another embodiment, the chalcogenide thin film material is an electrical switching material that can be switched from a high resistance state to a low resistance state upon application of a threshold voltage, where the low resistance state includes at least a filamentary portion that exhibits high conductivity.

In another embodiment, the chalcogenide thin film material is an electrical memory material in which the relative proportions of crystalline and amorphous phase volumes can be varied through the application of an electrical signal, where the resistivity of the material varies with the relative proportions of crystalline and amorphous phase content.

In one embodiment, the thin film chalcogenide material comprises Te. In another embodiment, the thin film chalcogenide material comprises Te and Ge. In yet another embodiment, the thin film chalcogenide material comprises Te and Sb. In one embodiment, the thin film chalcogenide material comprises Se. In another embodiment, the thin film chalcogenide material comprises Se and Ge. In yet another embodiment, the thin film chalcogenide material comprises Se and Sb.

For a better understanding of the instant invention, together with other and further illustrative objects thereof, reference is made to the following description, taken in conjunction with the accompanying drawings and claims.

### BRIEF DESCRIPTION OF THE DRAWINGS

FIG. 1 is a depiction of the I-V characteristics of a switching material that exhibits a transformation from a resistive state to a conductive state upon application of a threshold voltage.

FIG. 2 is a depiction of the R-I characteristics of a programmable resistance memory material, such as a chalcogenide phase-change material.

FIG. 3 is a schematic depiction of a heating apparatus used to form materials in accordance with the process of the instant invention.

FIG. 4 presents the results of EDX compositional analysis of a thin film chalcogenide material.

FIG. 5 is an SEM image of a thin film chalcogenide material.

FIG. 6 is an SEM image of a thin film chalcogenide material.

FIG. 7 is a schematic depiction of a deposition surface having a patterned feature.

FIG. 8 is an SEM image of a thin film chalcogenide material formed in the patterned feature depicted in FIG. 7 and having upper carbon and Pt layers.

FIG. 9 is an SEM image of a thin film chalcogenide material formed in the patterned feature depicted in FIG. 7 and having an upper electrode layer.

FIG. 10 shows the I-V response of a device having the structure depicted in FIG. 9.

FIG. 11 shows the R-I response of a device having the structure depicted in FIG. 9.

FIG. 12 shows the endurance characteristics of a device having the structure depicted in FIG. 9.

### DETAILED DESCRIPTION OF THE ILLUSTRATED EMBODIMENTS

Although this invention will be described in terms of certain preferred embodiments, other embodiments that are apparent to those of ordinary skill in the art, including embodiments that do not provide all of the benefits and features set forth herein, are also within the scope of this invention. Accordingly, the scope of the invention is defined only by reference to the appended claims.

The instant invention provides a method for forming chalcogenide memory and electrical switching materials. The method includes vaporizing a condensed phase chalcogenide source material and depositing a chalcogenide product material on a deposition surface spaced apart from the source material. In order to better appreciate the illustrative examples of the instant invention presented hereinbelow, it is helpful to review the basic operational characteristics of phase-change and electrical switching materials.

As indicated above, an important feature of the chalcogenide phase-change family of materials used in optical and electrical memory applications is their ability to undergo a phase transformation between two or more structural states. The chalcogenide phase-change materials have structural states that include a crystalline state, one or more partially-crystalline states and an amorphous state. A partially-crystalline state refers to a structural state in which a volume of chalcogenide or phase-change material includes an amorphous portion and a crystalline portion. Generally, a plurality of partially-crystalline states exists for the chalcogenide or phase-change material that may be distinguished on the basis of the relative proportion of the amorphous and crystalline portions. Fractional crystallinity is one way to characterize the structural states of a chalcogenide phase-change material. The fractional crystallinity of chalcogenide phase-change materials may vary from 0% (the amorphous limit) continuously through a series of partially crystalline states having increased fractional crystallinity up to 100% (the crystalline limit).

Transformations among the structural states are induced by providing energy to the chalcogenide material. Energy in various forms can induce structural transformations of the crystalline and amorphous portions and thus can influence the fractional crystallinity of a chalcogenide material. Suitable forms of energy include one or more of electrical energy, thermal energy, optical energy or other forms of energy (e.g. particle-beam energy) that induce electrical, thermal or optical effects in a chalcogenide material. Continuous and reversible variability of the fractional crystallinity is achievable by controlling the energy environment of a chalcogenide material. A crystalline state can be transformed to a partially-crystalline or an amorphous state, a partially-crystalline state can be transformed to a crystalline, amorphous or different partially-crystalline state, and an amorphous state can be transformed to a partially-crystalline or crystalline state through proper control of the energy environment of a chalcogenide material. Some considerations associated with the use of thermal, electrical and optical energy to induce structural transformations are presented in the following discussion.

The use of thermal energy to induce structural transformations exploits the thermodynamics and kinetics associated with the crystalline to amorphous or amorphous to crystalline phase transitions. An amorphous phase may be formed, for example, from a partially-crystalline or crystalline state by heating a chalcogenide material above its melting temperature and cooling at a rate sufficient to inhibit the formation of crystalline phases. A crystalline phase may be formed from an amorphous or partially-crystalline state, for example, by heating a chalcogenide material above the crystallization temperature for a sufficient period of time to effect nucleation and/or growth of crystalline domains. The crystallization temperature is below the melting temperature and corresponds to the minimum temperature at which crystallization may occur. The driving force for crystallization is typically thermodynamic in that the free energy of a crystalline or partially-crystalline state in many chalcogenide materials is lower than the free energy of an amorphous state so that the overall energy of a chalcogenide material decreases as the fractional crystallinity increases. Formation (nucleation and growth) of a crystalline state or crystalline domains within a partially-crystalline or amorphous state is kinetically enabled up to the melting temperature, so that heating promotes crystallization by providing energy that facilitates the rearrangements of atoms needed to form a crystalline phase or domain. The fractional crystallinity of a partially-crystalline state can be controlled by controlling the temperature or time of heating of the partially-crystalline state or by controlling the temperature or rate of cooling of an amorphous or partially-crystalline state. Through proper control of the peak temperature, time of heating and rate of cooling, structural states over the full range of fractional crystallinity can be achieved for the chalcogenide phase-change materials.

The use of electrical energy to induce structural transformations relies on the application of electrical (current or voltage) pulses to a chalcogenide material. The mechanism of electrically-induced structural transformations includes Joule heating created by resistance to current flow. Joule heating corresponds to a conversion of electrical energy to thermal energy and leads to an increase in the temperature of the chalcogenide material. By controlling the current density, the temperature can be controlled.

The crystalline phase portions of a chalcogenide material are sufficiently conductive to permit current densities that provide efficient Joule heating. The amorphous phase portions, however, are much less conductive and ordinarily would not support current densities sufficient to heat the material to the crystallization temperature. As described more fully hereinbelow, however, the amorphous phase of many chalcogenide materials can be electrically switched to a highly conductive intermediate state upon application of a voltage greater than the threshold voltage. In the intermediate state, the material can support a current density that is high enough to heat the material to the crystallization temperature through Joule heating. By controlling the magnitude and/or duration of electrical pulses applied to a chalcogenide phase-change material, it is possible to vary continuously the fractional crystallinity through controlled interconversion of the crystalline and amorphous phases.

The influence of electrical energy on a chalcogenide material is generally depicted in terms of the I-V (current-voltage) and R-I (resistance-current) relationships of the material. The I-V relationship shows the current response of a chalcogenide material as a function of applied voltage and the R-I relationship shows the variation of the electrical resistance of a chalcogenide material as a function of the amount of electrical energy provided or as a function of the magnitude of the current or voltage pulse applied to a chalcogenide material. A brief discussion of the I-V and R-I characteristics of chalcogenide materials follows.

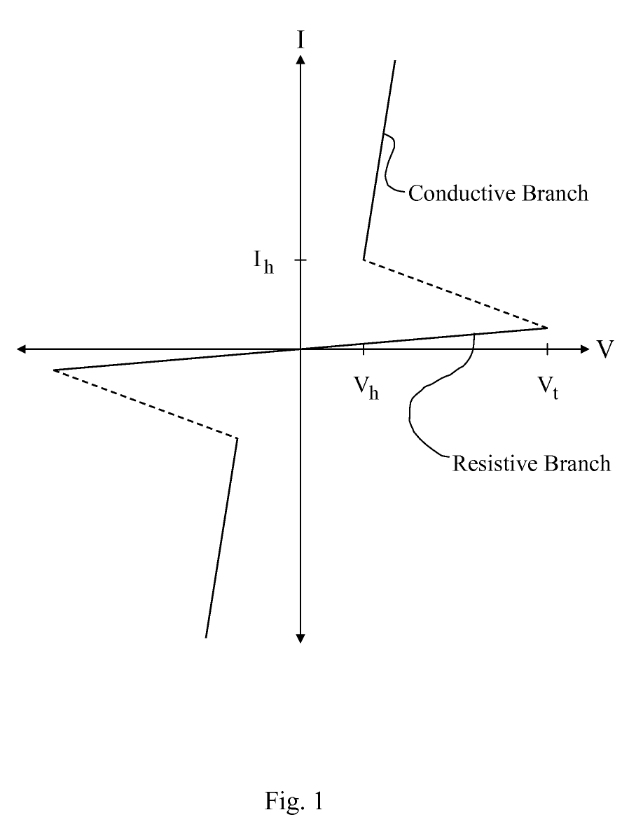

The I-V response of many chalcogenide materials exhibits an electrical switching event in which the chalcogenide material undergoes a transformation from a more resistive state to a more conductive state. A schematic depiction of the electrical switching event is presented in FIG. 1. The depiction of FIG. 1 corresponds to a two-terminal device configuration in which two spacedly disposed electrodes are in contact with a chalcogenide material and the current I corresponds to the current passing between the two electrodes. The I-V curve of FIG. 1 shows the current passing through the chalcogenide material as a function of the voltage applied across the material by the electrodes. The I-V characteristics of the material are symmetric with respect to the polarity of the applied voltage. For convenience, we consider the first quadrant of the I-V plot of FIG. 1 (the portion in which current and voltage are both positive) in the discussion of chalcogenide switching behavior that follows. An analogous description that accounts for polarity applies to the third quadrant of the I-V plot.

The I-V curve includes a resistive branch and a conductive branch. The branches are labeled in FIG. 1. The resistive branch corresponds to the regime in which the current passing through the material is a weak function of the applied voltage across the material. This branch exhibits a small slope in the I-V plot and appears as a nearly horizontal line in the first and third quadrants of FIG. 1. The conductive branch corresponds to the regime in which the current passing through the material is highly sensitive to the voltage applied across the material. This branch exhibits a large slope in the I-V plot and appears as a nearly vertical line in the first and third quadrants of FIG. 1. The slopes of the resistive and conductive branches shown in FIG. 1 are illustrative and not intended to be limiting, the actual slopes will depend on the chemical composition of the chalcogenide material, device geometry, circuit configuration, and electrical contacts. Regardless of the actual slopes, the conductive branch exhibits a larger slope than the resistive branch. When device conditions are such that the chalcogenide material is described by a point on the resistive branch of the I-V curve, the chalcogenide material or device may be said to be in a resistive state. When device conditions are such that the chalcogenide material is described by a point on the conductive branch of the I-V curve, the chalcogenide material or device may be said to be in a conductive state.

The switching properties of the chalcogenide material are shown in FIG. 1. We begin with a device that has no voltage applied across it. When no voltage is applied across the chalcogenide material, the material is in a resistive state and no current flows. This condition corresponds to the origin of the I-V plot shown in FIG. 1. The chalcogenide material remains in a resistive state as the applied voltage is increased, up to a threshold voltage (labeled Vₜ in the first quadrant of FIG. 1). The slope of the I-V curve for applied voltages between 0 and Vₜ is small in magnitude and indicates that the chalcogenide material has a high electrical resistance. The high resistance implies low electrical conductivity and as a result, the current flowing through the material increases only weakly as the applied voltage is increased. Since the current through the material is very small, the resistive state of the chalcogenide may be referred to as the OFF state of the material. In the conductive “ON” state, the IV does not exhibit a threshold voltage, but goes directly from a more conducting state into the dynamic state with no need to threshold.

When the applied voltage equals or exceeds the threshold voltage, the chalcogenide material transforms (switches) from the resistive branch to the conductive branch of the I-V curve. The switching event occurs essentially instantaneously and is depicted by the dashed line in FIG. 1. Upon switching, the device voltage decreases significantly and the device current becomes much more sensitive to changes in the device voltage. The chalcogenide material remains in the conductive branch as long as a minimum current, labeled Iₕ in FIG. 1, is maintained. We refer to Iₕ as the holding current and the associated voltage Vₕ as the holding voltage of the device. If the device conditions are changed so that the current becomes less than Iₕ, the material normally returns to the resistive branch of the I-V plot and requires subsequent application of a threshold voltage to resume operation on the conductive branch. If the current is only momentarily (a time less than the recovery time of the chalcogenide material) reduced below Iₕ, the conductive state of the chalcogenide material may be recovered upon restoring the current to or above Iₕ. The recovery time of chalcogenide materials has been discussed in the article “Amorphous Semiconductors for Switching, Memory, and Imaging Applications”, IEEE Transactions on Electron Devices, vol. ED-20, p. 91-105 (1973) by S. R. Ovshinsky and H. Fritzsche; the disclosure of which is incorporated by reference herein.

The switching effect of the instant devices originates from a transformation of the chalcogenide material from a resistive state to a conductive state upon application of a threshold voltage, Vₜₕ. According to one model of the switching transformation, application of the threshold voltage causes the formation of a conductive channel or filament within the chalcogenide material. At the threshold voltage, the electric field experienced by the material is sufficiently high to induce a breakdown or avalanche effect whereby electrons are removed from atoms to form a highly conductive, plasma-like filament of charge carriers. Rather than being bound to atoms, some electrons become unbound and highly mobile. As a result, a conductive channel or filament forms. The conductive filament constitutes a conductive volume within the otherwise resistive chalcogenide material. The conductive filament extends through the chalcogenide material between the device terminals and provides a low resistance pathway for electrical current. Portions of the chalcogenide material outside of the filament remain resistive. Since electric current traverses the path of least resistance, the presence of a conductive filament renders the chalcogenide material conductive and establishes a conductive state. The creation of a conductive filament is the event that underlies the switching of the chalcogenide material from a resistive state to a conductive state.

The conductive filament is maintained between the device terminals as long as the device current remains at or above the holding current. A conductive filament is present for all points along the conductive branch, but the cross sectional area of the filament differs for different points along the conductive branch. Depending on operating conditions within the conductive branch, the filament can be narrow or wide. As the applied voltage is increased along the conductive branch, the cross section of the filament is enlarged as the applied voltage is increased. The enlarged filament indicates a greater volume of the chalcogenide material exhibits high conductivity. During the time the filament enlarges, the voltage across the contacts remains constant. When the filament reaches the dimensions of the pore, it can no longer grow and its resistivity must increase. As a result, the chalcogenide material can support a greater current, as indicated by the conductive branch of the I-V curve, when the applied voltage increases. Variations of the voltage applied to a chalcogenide material operating in the conductive branch modify the width or thickness of the filament in directions lateral to the direction of current flow. The net effect of varying the applied voltage of a chalcogenide material operating in the conductive branch is to modify the volume fractions of the conductive and resistive portions (unless the material is melted and quenched).

Chalcogenide materials of many chemical compositions undergo the foregoing switching effect. Representative chalcogenide materials are those that include one or more elements from column VI of the periodic table (the chalcogen elements) and optionally one or more chemical modifiers from columns III, IV or V. One or more of S, Se, and Te are the most common chalcogen elements included in the active material of the instant devices. The chalcogen elements are characterized by divalent bonding and the presence of lone pair electrons. The divalent bonding leads to the formation of chain and ring structures upon combining chalcogen elements to form chalcogenide materials and the lone pair electrons provide a source of electrons for forming a conducting filament. Trivalent and tetravalent modifiers such as Al, Ga, In, Ge, Sn, Si, P, As and Sb enter the chain and ring structures of chalcogen elements and provide points for branching and crosslinking. The structural rigidity of chalcogenide materials depends on the extent of crosslinking and leads to a broad classification of chalcogenide materials, according to their ability to undergo crystallization or other structural rearrangements, into one of two types: threshold switching materials and phase-change (or memory) materials.

In one embodiment of the instant invention, the switching material includes Se or Te. In another embodiment, the atomic concentration of Se or Te in the switching material is at least 30%. In a further embodiment, the atomic concentration of Se or Te in the switching material is at least 50%. As used herein atomic concentration refers to the percent abundance of an element in molar or atomic terms. In the composition As₂Te₃Ge, for example, the mole fraction of Te is 0.50 and the atomic concentration of Te is 50%. In another embodiment, the switching material includes Se or Te along with Ge or In. In a further embodiment, the switching material includes Se or Te, Ge or In, and one or more of Si, Sb and As. Representative switching materials include Si₁₄Te₃₉As₃₇Ge₉X (X═In or P), As—Te—Ge—Si alloys, As₂Te₃Ge, As₂Se₃Ge, As₂₅(Te₉₀Ge₁₀)₇₅, Te₄₀As₃₅Si₁₈Ge_{6.75}In_{0.25}, Te₂₈As_{34.5}Ge_{15.5}S₂₂, Te₃₉As₃₆Si₁₇Ge₇P, As₁₀Te₂₁S₂Ge₁₅Se₅₀Sb₂, and Si₅Te₃₄As₂₈Ge₁₁S₂₁Se₁. Illustrative compositions for switching materials are discussed in U.S. Pat. Appl. Pub. Nos. 20060118911, 20060171194, 20060291272, 20070096090, 20070105267, and in U.S. Pat. Nos. 3,748,501; 4,845,533; 5,543,737; 5,694,146; 5,757,446; 6,795,338; 6,967,344; and 6,969,867 the disclosures of which are incorporated by reference herein.

The chalcogenide phase-change materials include compositions in the alloy families binary Ge—Te compositions, ternary Ge—Sb—Se compositions, ternary In—Sb—Se compositions, ternary Ge—Sn—Te compositions, binary Ga—Sb compositions, binary In—Sb compositions, binary In—Se compositions, Sb₂Te₃, Ge₂Sb₂Te₅, ternary Ge—Sb—Te compositions, In₂Sb₂Te₅, ternary In—Sb—Te compositions, ternary GaSeTe compositions, TAG and other ternary Te—As—Ge compositions, GaSeTe, SnSb₂Te₄, ternary In—Sb—Ge compositions, quaternary Ag—In—Sb—Te compositions, quaternary Ge—Sn—Sb—Te compositions, quaternary Ge—Sb—Se—Te compositions, and quaternary Te—Ge—Sb—S compositions. Chalcogenide phase-change compositions are discussed in U.S. Pat. Nos. 3,748,501 5,335,219 5,406,509 6,967,344; 6,969,867; 7,020,006 5,543,737; 5,694,146; 5,757,446; 5,166,758; 5,296,716; 5,534,711; 5,536,947; 5,596,522; 6,087,674; and 7,186,998; the disclosures of which are incorporated by reference herein.

Both types of chalcogenide materials display the switching behavior shown in FIG. 1, but differ in their structural response to filament formation. The threshold switching materials generally possess a higher concentration of modifiers and are more highly crosslinked than the phase-change materials. They are accordingly more rigid structurally. Threshold switching materials are amorphous and show little or no tendency to crystallize because the atomic rearrangements required to nucleate and grow a crystalline phase are inhibited by the rigidity of the structure. Threshold switching materials do not undergo a crystallization transformation during switching and remain amorphous upon removing the applied voltage after switching.

Phase-change chalcogenide materials, on the contrary, are lightly crosslinked and more easily undergo full or partial crystallization. An amorphous phase-change material undergoes filament formation in the presence of a threshold voltage as described in FIG. 1 hereinabove. Once in the conductive branch, however, the phase-change material may undergo nucleation and growth of a crystalline phase. The volume fraction of the crystalline phase depends on the magnitude and time of the current passing through the phase-change material. If formed, the crystalline phase is retained upon removing the applied voltage after switching. Through appropriate selection of device operating conditions, the amorphous-crystalline transformation of chalcogenide phase-change memory materials becomes reversible over many cycles.

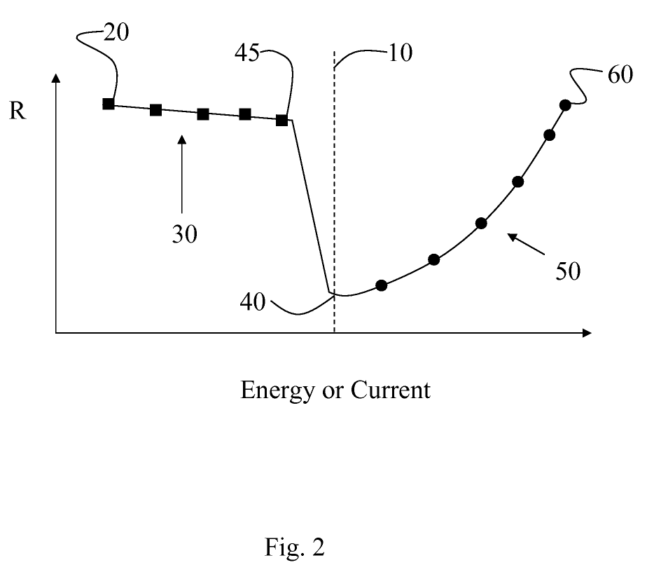

The R-I response is a meaningful depiction of the characteristics of the chalcogenide phase-change materials and provides a representation of the effect of structural transformations associated with the crystalline-amorphous phase-change process on electrical properties. A representative depiction of the electrical resistance (R) of a chalcogenide material as a function of electrical energy or current pulse magnitude (Energy/Current) is presented in FIG. 2. FIG. 2 may generally be referred to as a resistance plot.

The resistance plot includes two characteristic response regimes of a chalcogenide material to electrical energy. The regimes are approximately demarcated with the vertical dashed line 10 shown in FIG. 2. The regime to the left of the line 10 may be referred to as the accumulating regime of the chalcogenide material. The accumulation regime is distinguished by a nearly constant or gradually varying electrical resistance with increasing electrical energy until a highly conducting state is reached. In most cases there is a region where device temperatures favor crystalline growth and when a percolation path occurs the resistance drop is very pronounced. The accumulation regime thus extends, in the direction of increasing energy, from the leftmost point 20 of the resistance plot, through a plateau region (generally depicted by 30) corresponding to the range of points over which the resistance variation is small or gradual to the set point or state 40 that follows an abrupt decrease in electrical resistance. The plateau 30 may be horizontal or sloping.

The left side of the resistance plot is referred to as the accumulating regime because the structural state of the chalcogenide material cumulatively evolves as energy is applied. The fractional crystallinity of the structural state correlates with the total accumulation of applied energy. The leftmost point 20 corresponds to the structural state in the accumulating regime having the lowest fractional crystallinity and may be referred to as the reset state. This state may be fully amorphous or may be primarily amorphous with some degree of crystalline content. As energy is added, the chalcogenide material progresses among a plurality of partially-crystalline states with increasing fractional crystallinity along the plateau 30. Selected accumulation states (structural states in the accumulation region) are marked with squares in FIG. 2.

Upon accumulation of a sufficient amount of applied energy, the fractional crystallinity of the chalcogenide material increases sufficiently to effect a setting transformation characterized by a dramatic decrease in electrical resistance and stabilization of the set state 40. The structural states in the accumulation regime may be referred to as accumulation states of the chalcogenide material. Structural transformations in the accumulating regime are unidirectional in the sense that they progress in the direction of increasing applied energy within the plateau region 30 and are reversible only by first driving the chalcogenide material through the set point 40 and resetting (melting and quenching the device). Once the reset state is obtained, lower amplitude current pulses can be applied and the accumulation response of the chalcogenide material can be retraced. It is possible to reversibly transform between the set and reset states over multiple cycles of operation.

While not wishing to be bound by theory, the instant inventor believes that the addition of energy to a chalcogenide material in the accumulating regime leads to an increase in fractional crystallinity through the nucleation of new crystalline domains or growth of existing crystalline domains or a combination thereof. It is believed that the electrical resistance varies only gradually along the plateau 30 despite the increase in fractional crystallinity because the crystalline domains form or grow in relative isolation of each other so as to prevent the formation of a contiguous crystalline network that spans the chalcogenide material between the two device electrodes. This type of crystallization may be referred to as sub-percolation crystallization. The setting transformation coincides with a percolation threshold in which a contiguous, interconnected crystalline network forms within the chalcogenide material that bridges the space between the two electrodes of the device. Such a network may form, for example, when crystalline domains increase sufficiently in size to impinge upon neighboring domains. Since the crystalline phase of chalcogenide materials is more conductive and less resistive than the amorphous phase, the percolation threshold corresponds to the formation of a contiguous low resistance conductive pathway through the chalcogenide material. As a result, the percolation threshold is marked by a dramatic decrease in the resistance of the chalcogenide material. The leftmost point 20 of the accumulation regime may be an amorphous state or a partially-crystalline state lacking a contiguous crystalline network. Sub-percolation crystallization commences with an initial amorphous or partially-crystalline state and progresses through a plurality of partially-crystalline states having increasingly higher fractional crystallinities until the percolation threshold is reached and the setting transformation occurs.

The regime to the right of the line 10 of FIG. 2 may be referred to as the direct overwrite regime. The direct overwrite regime extends from the set state 40 through a plurality of intermediate states (generally depicted by 50) to a reset point or state 60. The various points in the direct overwrite regime may be referred to as direct overwrite states of the chalcogenide material. Selected direct overwrite states are marked with circles in FIG. 2. Structural transformations in the direct overwrite regime may be induced by applying an electric current or voltage pulse to a chalcogenide material. In FIG. 2, an electric current pulse is indicated. In the direct overwrite regime, the resistance of the chalcogenide material varies with the magnitude of the applied electric pulse. The resistance of a particular direct overwrite state is characteristic of the structural state of the chalcogenide material, and the structural state of a chalcogenide material is dictated by the magnitude of the applied current pulse. The fractional crystallinity of the chalcogenide material decreases as the magnitude of the current pulse increases. The fractional crystallinity is highest for direct overwrite states at or near the set point 40 and progressively decreases as the reset state 60 is approached. The chalcogenide material transforms from a structural state possessing a contiguous crystalline network at the set state 40 to a structural state that is amorphous or substantially amorphous or partially-crystalline without a contiguous crystalline network at the reset state 60. The application of current pulses having increasing magnitude has the effect of converting portions of the crystalline network into an amorphous phase and ultimately leads to a disruption or interruption of contiguous high-conductivity crystalline pathways in the chalcogenide material. As a result, the resistance of the chalcogenide material increases as the magnitude of an applied current pulse increases in the direct overwrite region.

In contrast to the accumulating region, structural transformations that occur in the direct overwrite region are reversible and bi-directional. As indicated hereinabove, each state in the direct overwrite region may be identified by its resistance and an associated current pulse magnitude, where application of the associated current pulse magnitude induces changes in fractional crystallinity that produce the particular resistance state. Application of a subsequent current pulse may increase or decrease the fractional crystallinity of an existing resistance state of the chalcogenide material. If the subsequent current pulse has a higher magnitude than the pulse used to establish the existing state, the fractional crystallinity of the chalcogenide material decreases and the structural state is transformed from the existing state in the direction of the reset state along the direct overwrite resistance curve. Similarly, if the subsequent current pulse has a lower magnitude than the pulse used to establish the existing state, the fractional crystallinity of the chalcogenide material increases and the structural state is transformed from the existing state in the direction of the set state along the direct overwrite resistance curve.

The direct overwrite states of the chalcogenide material may be used to define memory states of a memory device. Most commonly, the memory devices are binary memory devices that utilize two of the direct overwrite states as memory states, where a distinct data value (e.g. “0” or “1”) is associated with each state. Each memory state thus corresponds to a distinct structural state of the chalcogenide material and readout or identification of the state can be accomplished by measuring the resistance of the material (or device) since each structural state is characterized by a distinct resistance value. The operation of transforming a chalcogenide material to the structural state associated with a particular memory state may be referred to herein as programming the chalcogenide material, writing to the chalcogenide material or storing information in the chalcogenide material.

To facilitate readout and to minimize readout error, it is desirable to select the memory states of a binary memory device so that the contrast in resistance of the two states is large. Typically the set state (or a state near the set state) and the reset state (or a state near the reset state) are selected as memory states in a binary memory application. The resistance contrast depends on details such as the chemical composition of the chalcogenide, the thickness of the chalcogenide material in the device and the geometry of the device. For a layer of phase-change material having the composition Ge₂₂Sb₂₂Te₅₆, a thickness of ˜600 Å, and pore diameter of below ˜0.1 μm in a typical two-terminal device structure, for example, the resistance of the reset state is ˜100-1000 kΩ and the resistance of the set state is under ˜10 kΩ. Phase-change materials in general show resistances in the range of ˜100 kΩ to ˜1000 kΩ in the reset state and resistance of ˜0.5 kΩ to ˜50 kΩ in the set state. In the preferred phase-change materials, the resistance of the reset state is at least a factor of two, and more typically an order of magnitude or more, greater than the resistance of the set state.

The instant invention provides a method for forming chalcogenide materials. The method entails vaporizing a condensed phase chalcogenide source material and condensing the resulting vapor on a deposition surface to form a product chalcogenide material. In one embodiment, vaporization is effected by heating the condensed phase chalcogenide source material. The heating may be achieved through a thermal process (e.g. oven heating), an optical process (e.g. laser heating or lamp heating), or electrical process (e.g. resistive heating). In one embodiment, vaporization occurs via a non-ionizing process. In another embodiment, vaporization occurs in a plasma-free environment.

In one embodiment, the heating may occur continuously at a steady temperature. In another embodiment, an interval of continuous heating at a steady temperature may be preceded by a ramp up in temperature and/or followed by a ramp down in temperature. In a further embodiment, the heating may occur intermittently or through cycling, where the heating is variable in time. In one embodiment, variable heating is achieved through pulsing of the source (thermal, optical, electrical) that provides the heat energy. In one embodiment, heating is accomplished through a rapid thermal anneal process. In one embodiment, the source material is heated to a temperature below its melting point. In another embodiment, the source material is heated to a temperature above its melting point. Heating may occur in the presence of a background or inert gas. Background or inert gases include argon or another noble gas, nitrogen, and hydrogen.

The condensed phase chalcogenide source material may be a solid-phase chalcogenide source material or a liquid-phase chalcogenide source material. In one embodiment, the condensed phase chalcogenide source material includes one or more of the chalcogen elements S, Se, or Te. In another embodiment, the condensed phase chalcogenide source material includes one or more of the chalcogen elements S, Se, or Te and one or more elements from column V of the periodic table (e.g. P, Sb, or As). In another embodiment, the condensed phase chalcogenide source material includes one or more of the chalcogen elements S, Se, or Te and one or more elements from column IV of the periodic table (e.g. Si, Ge, or Sn). In another embodiment, the condensed phase chalcogenide source material includes one or more of the chalcogen elements S, Se, or Te and one or more elements from column III of the periodic table (e.g. Ga or In). In another embodiment, the condensed phase chalcogenide source material includes one or more of the chalcogen elements S, Se, or Te along with one or more elements from column V of the periodic table (e.g. P, Sb, or As) and one or more elements from column IV of the periodic table (e.g. Si, Ge, or Sn). In another embodiment, the condensed phase chalcogenide source material includes one or more of the chalcogen elements S, Se, or Te along with one or more elements from column V of the periodic table (e.g. P, Sb, or As) and one or more elements from column III of the periodic table (e.g. Ga or In). In another embodiment, the condensed phase chalcogenide source material includes one or more of the chalcogen elements S, Se, or Te along with one or more elements from column IV of the periodic table (e.g. Si, Ge, or Sn) and one or more elements from column III of the periodic table (e.g. Ga or In). The chalcogenide source material may be a binary, ternary, quaternary, or higher multiplicity composition. In a further embodiment, the chalcogenide source material is substantially free of one or more of the elements carbon, nitrogen, and hydrogen.

In one embodiment, the instant deposition process may be achieved by vaporizing a plurality of condensed phase source materials, each of which contains an element for incorporation into the product. In this embodiment, each condensed phase source material is vaporized to form a vapor containing at least one element that is ultimately incorporated into the product upon condensation. The different condensed phase source materials may be heated to the same or different temperature. Each condensed phase source material may sublime or evaporate to form a vapor and the invention contemplates that some source materials may sublime, while others may evaporate during a particular deposition process. As an example, a Ge—Sb—Te product may be formed by producing vapors from separate Ge, Sb, and Te sources positioned within the deposition apparatus and co-condensing the vapors on a deposition surface. The separate sources may be element sources or multielement sources. A Ge—Sb—Te product may be formed, for example, by vaporizing a Ge—Te source material and a separate Sb source material. Alternatively, a Ge—Sb—Te product may be formed by vaporizing a Ge—Sb source material and a separate Te source material. Similarly, a Ge—Sb—Te product may be formed by vaporizing a Te—Sb source material and a separate Ge source material.

The product chalcogenide material is typically a thin film chalcogenide material. In one embodiment, the product is formed in an amorphous phase. The product includes a chalcogen element that originated from the condensed phase chalcogenide source material. In one embodiment, the atomic concentration of the chalcogen element in the product is between 95% and 105% of the atomic concentration of the chalcogen element in the source material. In another embodiment, the atomic concentration of the chalcogen element in the product is between 90% and 110% of the atomic concentration of the chalcogen element in the source material. In still another embodiment, the atomic concentration of the chalcogen element in the product is between 80% and 120% of the atomic concentration of the chalcogen element in the source material. In a further embodiment, the atomic concentration of the chalcogen element in the product is between 70% and 130% of the atomic concentration of the chalcogen element in the source material.

By way of example, if the condensed phase chalcogenide source material is Ge₂Sb₂Te₅, the chalcogen element is Te and its atomic concentration is 55.56%. If this exemplary source material is heated to form a vapor and the vapor is condensed on a deposition surface to form a product in accordance with the instant invention, the product includes Te. In one embodiment, the atomic concentration of Te is between 95% of 55.56% (52.78%) and 105% of 55.56% (58.34%). In another embodiment, the atomic concentration of Te is between 90% of 55.56% (50.00%) and 110% of 55.56% (61.11%). In still another embodiment, the atomic concentration of Te is between 80% of 55.56% (44.45%) and 120% of 55.56% (66.67%). In a further embodiment, the atomic concentration of Te is between 70% of 55.56% (38.89%) and 130% of 55.56% (72.23%).

Independently of or in addition to the chalcogen element, the atomic concentration of one or more other elements (e.g. elements from columns III, IV, or V) in the product condensed from a vapor phase formed from the chalcogenide source material may also be within the ranges indicated above with respect to the atomic concentration of the same element in the chalcogenide source material. To continue with the example of Ge₂Sb₂Te₅ above, Sb is a column V element and Ge is a column IV element. The atomic concentration of each of Sb and Ge is 22.22%. In one embodiment, the atomic concentration of either or both of Sb and Ge is between 95% of 22.22% (21.11%) and 105% of 22.22% (23.33%). In one embodiment, the atomic concentration of either or both of Sb and Ge is between 90% of 22.22% (20.00%) and 110% of 22.22% (24.44%). In one embodiment, the atomic concentration of either or both of Sb and Ge is between 80% of 22.22% (17.78%) and 120% of 22.22% (26.66%). In one embodiment, the atomic concentration of either or both of Sb and Ge is between 70% of 22.22% (15.55%) and 130% of 22.22% (28.89%).

The close fit between the atomic concentration of one or more (up to all) of the elements in the product chalcogenide material and the source chalcogenide material is a benefit of the instant invention. The source material is a chalcogenide material that includes a chalcogen element along with one or more other elements in a particular stoichiometric ratio. Each element is bonded with at least one other element. When elements are present in the form of a compound in the source material, the physical properties (e.g. melting point, vapor pressure, sublimation pressure) are controlled by the compound instead of the elements individually. As a result, when the source material vaporizes, there is a greater tendency for the elements to escape in accordance with the relative proportions defined by the stoichiometric proportions in the compound. As a result, the composition of the condensed product formed from the vapor is more likely to match that of the source material.

If the individual elements are used as source materials in a vaporization process, it may be more difficult to control the relative rates of delivery of the individual elements to the deposition surface to achieve a desired composition in the product phase than if a multielement or compound source material is used. Each element has different vaporization tendencies and to form a product phase having a particular stoichiometry, it is necessary to coordinate delivery of the different elements in space and time to insure that the proportions desired in the product phase are represented at the deposition surface. In the case of Ge₂Sb₂Te₅, for example, use of elemental Ge, Sb, and Te as source materials requires control over the vaporization processes of elements that differ in melting point, vapor pressure, and sublimation pressure. As a result, it may require careful optimization of process conditions to achieve the 2:2:5 stoichiometric ratio present in Ge₂Sb₂Te₅. As demonstrated in the illustrative examples described hereinbelow, when Ge₂Sb₂Te₅ is used as the source material, a product material having a stoichiometric ratio of or close to 2:2:5 is readily achieved. It is similarly possible to achieve product materials having a wide range of stoichiometric proportions that conform closely to the stoichiometric composition of a source material.

A further advantage of the instant invention is the ability to control the phase of the product material. The phase of the chalcogenide source material and the phase of the product material may differ. In one embodiment, the chalcogenide source material is a crystalline or polycrystalline material and the product material is an amorphous phase material having an atomic concentration of one or more (up to all) elements within the ranges indicated hereinabove of their respective atomic concentration in the source material. Formation of an amorphous phase product having a desired stoichiometry is beneficial when it is desired to deposit of a chalcogenide material in or over a feature such as an opening (e.g. hole, trench, via), groove, depression, or step that may be present on the deposition surface. As noted above, conformal deposition in or over features is desirable to avoid gaps or incomplete filling and thus to insure better device performance. Formation of an amorphous phase product on the deposition surface promotes conformality of deposition by avoiding the granularity and non-space-filling tendencies of crystalline phase deposition.

At the same time, the instant invention recognizes that production of commercial quantities of source materials is often most economical for crystalline or polycrystalline forms of the source material. The instant invention therefore provides the benefit of low cost source materials with the advantage of more conformal deposition of a product that is faithful to the composition of the source material. Although a technique such as chemical vapor deposition may provide conformal deposition, it relies on costly precursor sources for the elements.

The deposition surface may be a planar surface or a surface that includes one or more features. Features include openings, holes, vias, trenches, recesses, depressions, grooves, edges and steps. The feature may be round, elliptical, bent, rectilinear or other circumferential shape. In one embodiment, condensation of the vapor phase formed from the source chalcogenide material occurs in a feature of the deposition surface to form a product material therein. In another embodiment, formation of the product material occurs conformally with the feature. In one embodiment, the opening is a circular hole that is filled or lined with a product chalcogenide material. In another embodiment, the opening is a trench that is filled or lined with a product chalcogenide material.

The feature may have an aspect ratio (ratio of the feature dimension normal to the deposition surface to the feature dimension lateral to or parallel to the deposition surface) that ranges between 0.25:1 and 5:1. In one embodiment, the aspect ratio of the feature is at least 0.5:1. In another embodiment of, the aspect ratio of the feature is at least 1:1. In yet another embodiment, the aspect ratio of the feature is at least 2:1. In a further embodiment, the aspect ratio of the feature is at least 3:1.

The deposition surface may be at the same or different temperature than the temperature of the source material. In one embodiment, the temperature of the deposition surface is less than the temperature of the source material. In another embodiment, the temperature of the deposition surface is less than the melting temperature of the source material. In another embodiment, the temperature of the deposition surface is less than the melting temperature of the product material. In another embodiment, the temperature of the deposition surface is less than the melting temperature of the source material. In another embodiment, the temperature of the deposition surface is less than the glass transition temperature of the source material.

Representative performance and benefits of the instant inventions are provided in the following examples. It is noted that the examples are illustrative only and do not serve to limit the scope of the invention. In particular, it is to be appreciated that compositions other than those selected to illustrate the instant invention are operable according to the principles of the instant invention.

### EXAMPLE 1

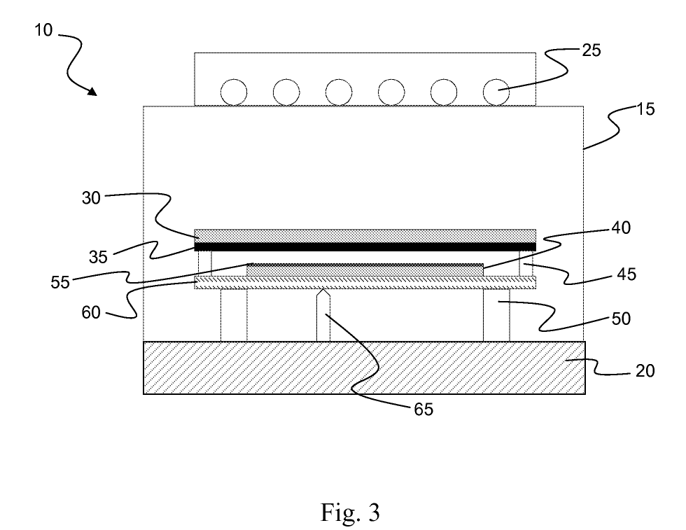

In this example, deposition of a thin film chalcogenide material on a planar surface via vaporization of a solid-phase chalcogenide source material is demonstrated. The apparatus used to perform the deposition is shown in FIG. 3, which shows heating apparatus 10 with enclosure 15, base 20 and quartz heaters 25. Upper wafer 30 was a 6″ silicon wafer that includes condensed phase chalcogenide source material 35. The source material was a solid-phase layer of Ge₂Sb₂Te₅ that was sputtered onto the surface of upper wafer 30. Upper wafer 30 and source material 35 were inverted and positioned above lower deposition wafer 40. Lower deposition wafer 40 was a 4″ silicon wafer having a planar surface for deposition of product chalcogenide material 55. Lower deposition wafer 40 was positioned on lower support wafer 60. Lower support wafer 60 was supported above base 20 with standoffs 50 and upper wafer 30 was supported above lower deposition wafer 40 with spacers 45. The separation between the exposed surface of condensed phase chalcogenide source material 35 and the deposition surface of lower deposition wafer 40 was ˜1 mm. Thermocouple 65 probes the temperature of lower support wafer 60.

To form product chalcogenide material 55, an inert gas (e.g. N₂ or Ar) is introduced to enclosure 15 and the pressure is reduced with a roughing vacuum pump. Deposition was initiated by turning on quartz heaters 25. Quartz heaters 25 were left on for a time window of ˜100 seconds to perform the deposition. During that time window, thermocouple 65 indicated that the temperature of lower support wafer 60 increased to a temperature of about 325° C. (which fluctuated slightly). The temperature increase of lower support wafer 60 lagged the turn on of quartz heaters 25 by about 10 seconds. During the time window of the experiment, solid-phase chalcogenide source material 35 vaporized and product chalcogenide material 55 formed on lower deposition wafer 40.

The time window of the experiment was kept short to prevent excessive heating of lower deposition wafer 40. To promote condensation of product chalcogenide material 55 on lower deposition wafer 40, it is desirable to insure that lower deposition wafer 40 remains cool relative to the upper wafer 30. When quartz heaters 25 are turned on, upper wafer 30 and solid-phase chalcogenide source material 35 heat up first. The heating of lower support wafer 60 is delayed and since lower deposition wafer 40 is shielded, its heating is delayed even more. If the time window of the experiment is kept short relative to the time needed to achieve full temperature equilibration, lower deposition wafer 40 (and product chalcogenide material 55) remained cooler than upper wafer 30 and solid-phase chalcogenide source material 35 during the deposition.

To conclude the deposition, quartz heaters 25 were turned off and lower deposition wafer 40 and product chalcogenide material 55 were allowed to cool to room temperature. A carbon layer was sputtered over product chalcogenide material 55 for subsequent SEM analysis. Inspection of upper wafer 30 revealed depletion of chalcogenide source material 35. The central portion of chalcogenide source material 35 was essentially fully depleted. A ring of chalcogenide material having a diameter of several inches was observed to surround the depleted source material. The surrounding ring may be the result of redeposition of chalcogenide material on upper wafer 30 during the deposition process.

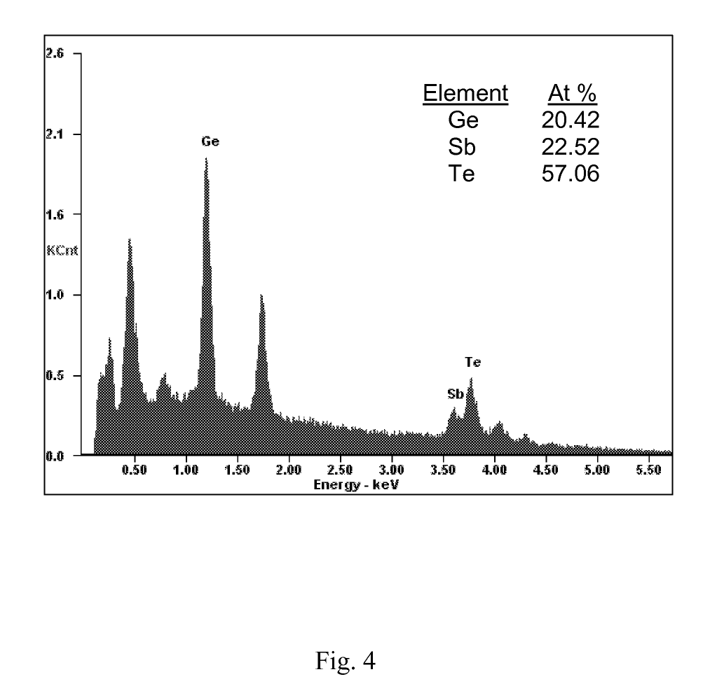

Product chalcogenide material 55 was characterized with EDX (energy dispersive x-ray) analysis and an SEM (scanning electron microscope) image on a cleaved layer. The EDX spectrum is shown in FIG. 4 for a typical location in product chalcogenide material 55 and the analysis indicated that product chalcogenide material 55 had an atomic concentration of Ge of 20.42%, an atomic concentration of Sb of 22.52%, and an atomic concentration of Te of 57.06%. These concentrations are very close to the composition of chalcogenide source material 35.

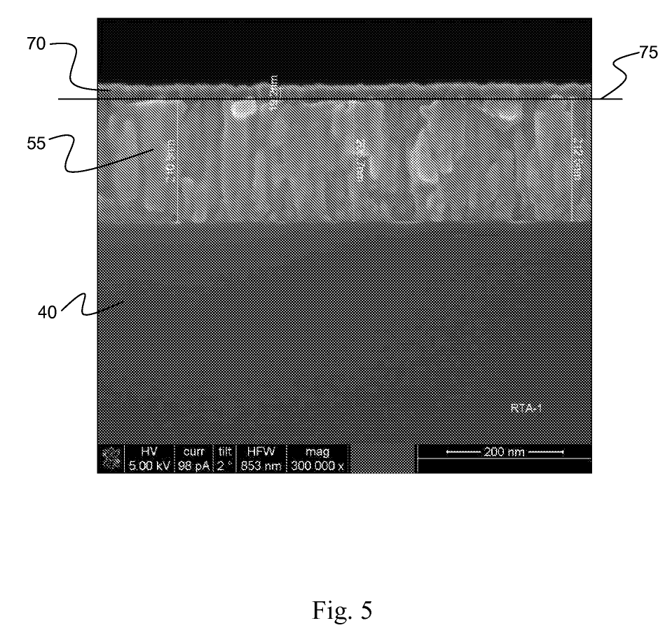

The SEM image is shown in FIG. 5. Product chalcogenide material 55, sputtered carbon layer 70 and a portion of deposition wafer 40 are shown in the image. The image indicates that product chalcogenide material 55 formed as a layer having a thickness of ˜210 nm and is capped by a sputtered carbon layer having a thickness of ˜19 nm. Line 75 marks the interface between carbon layer 70 and product chalcogenide material 55. Product chalcogenide material 55 appears as a columnar growth film, most likely polycrystalline material having a relatively uniform crystal size distribution. The smooth interface between product chalcogenide material 55 and carbon layer 70 suggests that product chalcogenide material 55 initially formed as an amorphous film and subsequently crystallized. If product chalcogenide material 55 initially formed as a crystalline material, the instant inventor would expect a more heterogeneous distribution of crystallite sizes and a rougher surface morphology for product chalcogenide material 55.

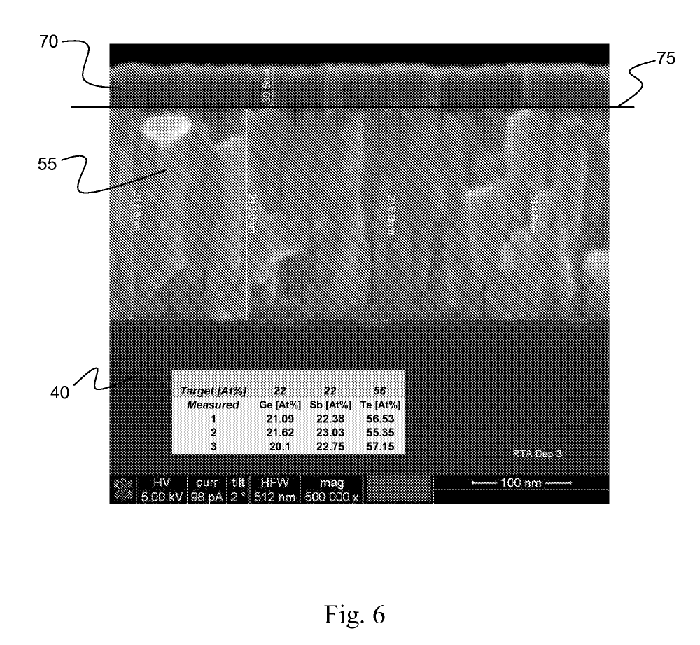

The experiment was repeated for a second trial on a planar lower deposition wafer and the resulting SEM image is shown in FIG. 6. The reference labels shown in FIG. 6 correspond to those described hereinabove for FIG. 5. FIG. 6 further includes a summary of EDX composition measurements made on product chalcogenide material 55 at three separate locations in the material. This trial confirms that the composition of product chalcogenide material 55 faithfully follows that of chalcogenide source material 35.

This example demonstrates that the instant invention permits deposition of a thin film product chalcogenide material through a process of vaporization of a solid-phase chalcogenide source material and condensation of the vapor on a remote deposition surface. Material from the source material is successfully transferred to a deposition surface to form a film that faithfully adheres to the composition of the source material.

### EXAMPLE 2

In this example, deposition of a thin film chalcogenide material within a patterned opening on a deposition surface via vaporization of a solid-phase chalcogenide source material is demonstrated. Except for lower deposition wafer 40, the apparatus, chalcogenide source material, and procedure of deposition are as described in Example 1 hereinabove. In this experiment, lower deposition wafer 40 was replaced with a deposition wafer that included a patterned feature. Specifically, the lower deposition wafer used in this experiment included a plurality of pore feature and deposition of a product chalcogenide material in these pores was achieved.

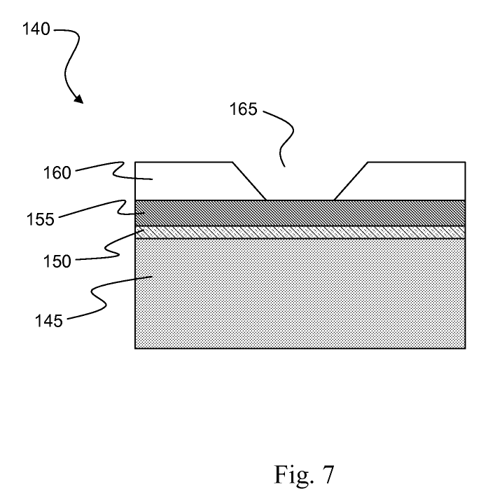

The pore feature of lower deposition wafer 140 shown schematically in FIG. 7 was used in this experiment. Lower deposition wafer 140 includes base wafer 145, oxide interface layer 150, lower electrode layer 155, and oxide layer 160 having a pore opening 165 formed therein. Base wafer 145 was a silicon wafer and oxide interface layer 150 was a layer of SiO₂. Lower electrode layer 155 was a TiAlN layer and oxide layer 160 was formed from SiO₂. Pore opening 165 is a circular opening having sloped sidewalls. A plurality of similar pore features having various pore diameters was present on the deposition surface of lower deposition wafer 140. Lower deposition wafer 140 was placed on lower support wafer 60 of heating apparatus 10 shown in FIG. 3 and deposition was commenced by heating chalcogenide source material 35. Chalcogenide product material 170 was formed over oxide layer 160 and within pore 165. After deposition of chalcogenide product material 170, a carbon layer 175 was formed over the chalcogenide product material and a Pt capping layer 180 was formed thereover. A plurality of similar pore structures was prepared across the surface of lower deposition wafer 140.

The chalcogenide product material of a representative structure was analyzed by SEM imaging and EDX compositional analysis. To complete the analysis, the structure was cleaved. The atomic concentrations of Ge, Sb, and Te in the chalcogenide product material at a representative location were determined to be 22.4%, 19.0%, and 58.6%; respectively. These concentrations are very close to the composition of chalcogenide source material 35.

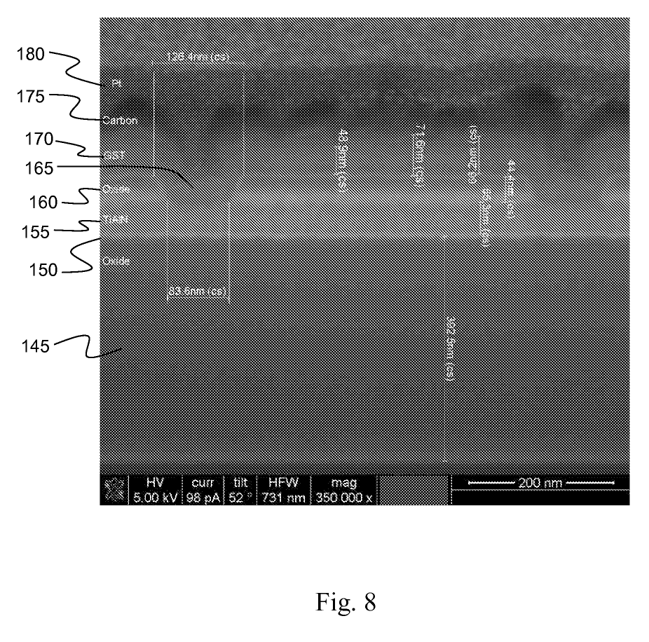

FIG. 8 shows a cross-sectional SEM image of the lower deposition wafer 140 after deposition. The image shows base wafer 145, oxide interface layer 150, lower electrode layer 155, oxide layer 160 having a pore opening 165, product chalcogenide material 170 (labeled “GST”), carbon layer 175, and Pt capping layer 180. Representative dimensions are as indicated in FIG. 8. The SEM image indicates good filling of pore 165 with product chalcogenide material 170. No indications of significant voiding or irregularities in the filling of pore 165 by product chalcogenide material 170 are evident in the SEM image. Instead, product chalcogenide material 170 fills pore 165 in a conformal or nearly conformal fashion.

### EXAMPLE 3

In this example, the electrical characteristics of a thin film chalcogenide material formed within a patterned opening of a deposition surface via vaporization of a solid-phase chalcogenide source material are determined.

The lower deposition wafer used for the experiments of this example was similar to lower deposition wafer 140 shown schematically in FIG. 7 and included base wafer 245, oxide interface layer 250, lower electrode layer 255, and oxide layer 260 having a pore opening 265 formed therein. Base wafer 245 was a silicon wafer and oxide interface layer 250 was a layer of SiO₂. Lower electrode layer 255 was a TiAlN layer and oxide layer 260 was formed from SiO₂. Pore opening 265 is a circular opening having sloped sidewalls. A plurality of similar pore features having various pore diameters was present on the deposition surface of the lower deposition wafer used for the experiments of this example. The lower deposition wafer was placed on lower support wafer 60 of heating apparatus 10 shown in FIG. 3 and deposition was commenced by heating chalcogenide source material 35. The heating conditions used in this example were similar to those used for Example 2 hereinabove. Chalcogenide product material 270 was formed over oxide layer 260 and within pore 265. After deposition of chalcogenide product material 270, a Ti/TiN upper electrode layer 285 was formed over the chalcogenide product material. A plurality of similar pore devices was prepared across the surface of the lower deposition wafer. Some of the devices were selected for SEM imaging and others were used to complete electrical testing.

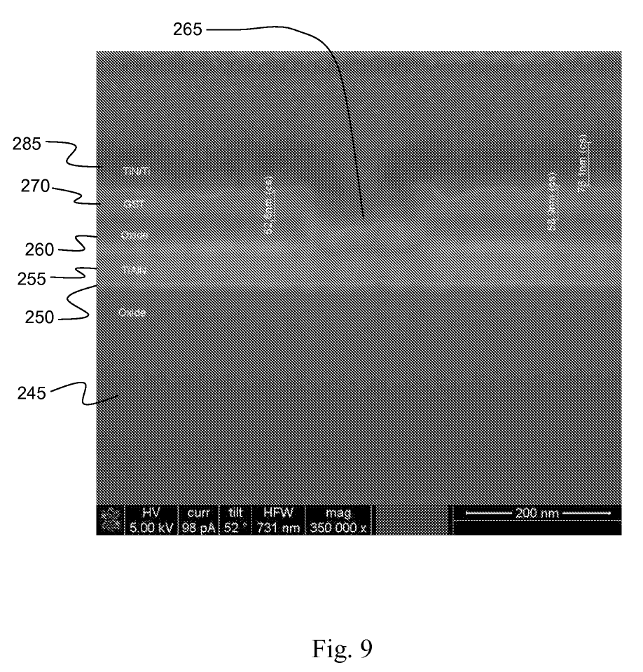

FIG. 9 shows a cross-sectional SEM image of a representative pore device formed on the lower deposition wafer by the instant vaporization process. The image shows base wafer 245, oxide interface layer 250, lower electrode layer 255, oxide layer 260 having a pore opening 265, product chalcogenide material 270 (labeled “GST”), and the Ti/TiN upper electrode layer 285. Selected dimensions are as indicated in FIG. 9. The SEM image indicates good filling of pore 265 with product chalcogenide material 270. No indications of significant voiding or irregularities in the filling of pore 265 by product chalcogenide material 270 are evident in the SEM image. Instead, product chalcogenide material 270 fills pore 265 in a conformal or nearly conformal fashion.

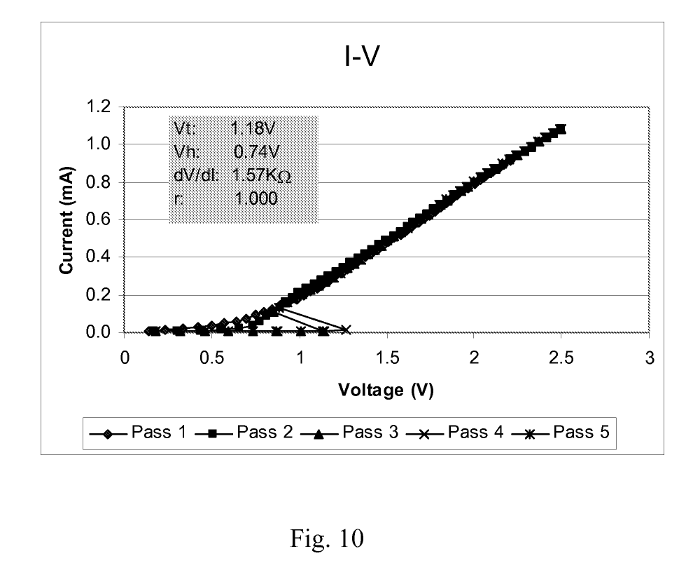

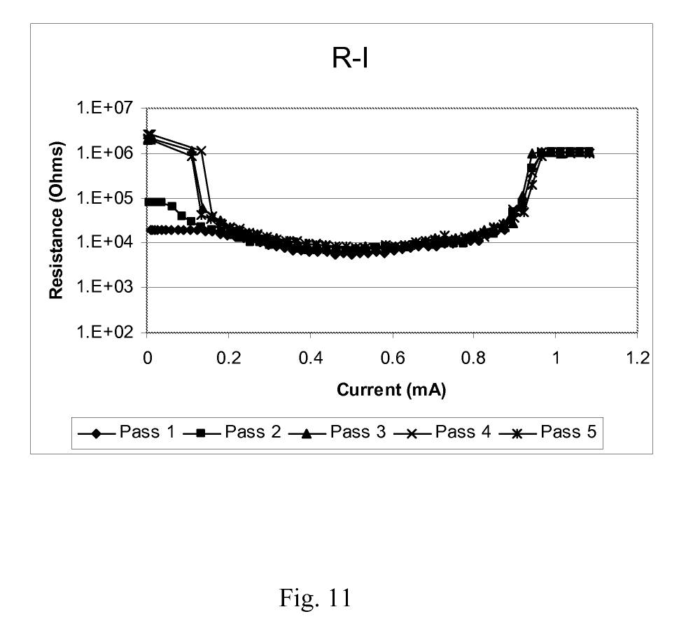

Selected devices from an uncleaved region of the lower deposition wafer were chosen to perform electrical testing to characterize performance attributes. The electrical tests were performed by attaching external leads to lower electrode layer 255 and upper electrode layer 285. The leads were connected to an electrical testing apparatus capable of delivering pulsed or constant electrical signals over a wide range of voltages, currents and waveforms. The electrical tests included measurements of the I (current)-V (voltage) and R (resistance)-I (current) characteristics of the tested device as described hereinabove in connection with FIGS. 1 and 2. The measurements were performed over several cycles of operation where for each cycle, a series of voltage pulses of progressively increasing amplitude was delivered from the testing apparatus to the device. The range of amplitude for the voltage pulses extended from ˜0.2 V up to ˜7 V and the different pulses in the series were separated by voltage increments of ˜0.1-0.15 V. The pulse duration was ˜500 ns. Electrical device characteristics were measured for each pulse delivered from the testing apparatus to the device. The voltage and current between lower electrode layer 255 and upper electrode layer 285 were measured while the pulse was applied and the resistance between lower electrode layer 255 and upper electrode layer 285 was measured upon conclusion of the pulse. After completion of the measurements at the maximum voltage amplitude, the procedure was repeated for additional cycles of operation. The results of the electrical testing are summarized in FIG. 10 and FIG. 11.

FIG. 10 shows the pulsed I-V response of the tested device over the first five cycles of operation. The data for each cycle of operation is indicated with a separate symbol as indicated in the legend of FIG. 10, where “pass 1” refers to the first cycle of operation, “pass 2” refers to the second cycle of operation etc. For the first two cycles of operation, the I-V response curve exhibited a monotonic increase in current with increasing voltage. Since the reset characteristics of the device are not known upon fabrication, it is necessary to estimate the voltage needed to provide a current sufficient to reset the device for the initial cycle of operation. For the device of this example, the maximum voltage used in the first pass was selected to be ˜6V. This voltage turned out to be insufficient to reset the device, so the maximum voltage was increased to ˜7V for the second cycle of operation. The data for the second cycle of operation indicated that ˜7V was sufficient to reset the device, so this voltage was used as the upper voltage limit for subsequent cycles.

Beginning with the third cycle of operation, the switchback response characteristic of the electrical switching event described hereinabove was observed. The switchback response was also observed for the fourth and fifth cycles of operation. A device conditioning period of a few cycles of operation following fabrication is commonly observed for phase-change devices. The data indicate that after conditioning, the device has a threshold voltage (Vₜ) of about 1.18 V, a holding voltage (Vₕ) of about 0.74 V and a dynamic resistance (derived from the slope of the conductive branch of the I-V response curve) of about 1.57 kΩ.

FIG. 11 shows the R-I response of the tested device over the first five cycles of operation. The initial resistance (resistance at zero current) of the tested device for the first two cycles (pass 1 and pass 2) was at or below ˜100 kΩ. As the current increased during each of the first two cycles, the resistance decreased to below 10 kΩ at intermediate currents and then increased at higher currents. As noted above, the upper voltage used for the first cycle of operation was insufficient to fully reset the device, so the first cycle of operation was concluded before the reset resistance of ˜1 MΩ was achieved. Since the final resistance after the first cycle of operation was below the reset resistance, the initial resistance of the second cycle of operation was also below the reset resistance. The final resistance of the second cycle of operation corresponded to the reset resistance, so that all subsequent cycles of operation began with the device in its reset state.

In the third cycle of operation, the R-I response of the device exhibited a high resistance (˜1 MΩ) at low currents followed by a pronounced decrease in resistance at ˜0.15 mA. The decrease in resistance corresponds to the set transformation of the device as described hereinabove. At still higher currents, the resistance of the device increases markedly and levels off at about 1 MΩ for currents above ˜0.95 mA. The leveling of the device resistance at the high end of the current range corresponds to the reset transition described in greater detail hereinabove. The R-I data indicate that the device has a set resistance of ˜10 kΩ and a reset resistance of ˜1 MΩ.

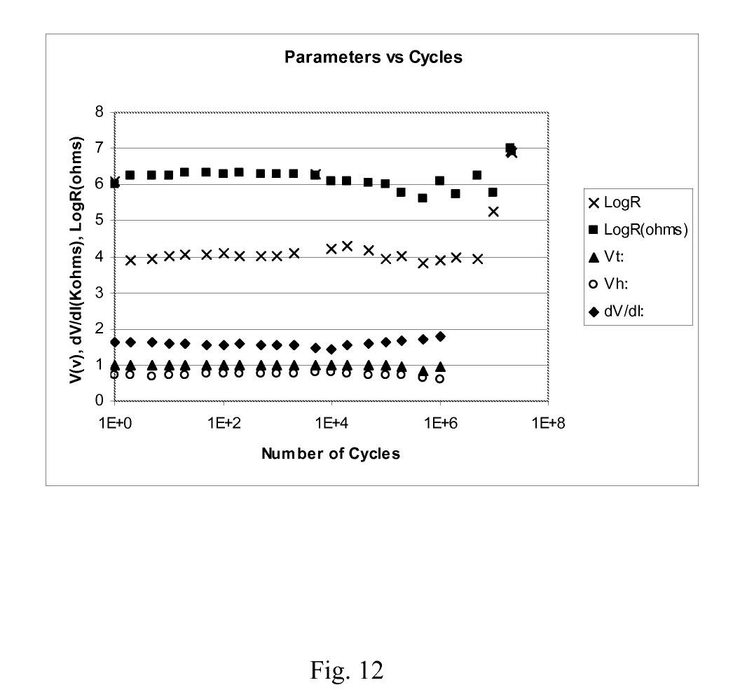

Testing of the device was continued beyond five operating cycles to test the endurance of the device. For practical devices, it is desirable for the device characteristics to remain stable over a large number of operating cycles. FIG. 12 summarizes the performance of the device over multiple cycles of operation. FIG. 12 presents the variation of reset resistance (data symbols “▪”, displayed on a log scale), set resistance (data symbols “×”, displayed on a log scale), threshold voltage Vₜ (data symbols “▴”), holding voltage Vₕ (data symbols “∘”), and dynamic resistance dV/dI (kΩ) (data symbols “♦”) as a function of cycle count. The endurance data indicate that the characteristics of the device remain stable for at least 10⁶ cycles and that the device fails as the cycle count approaches 10⁷.

The results of this example show that a chalcogenide material formed in accordance with the instant vaporization process displays the operational characteristics expected of phase-change memory materials. The conditioning response, set current, set resistance, reset current, reset resistance, cycling, and endurance characteristics of devices prepared in accordance with the instant invention are comparable to those observed for devices having a similar structure in which other methods were used to deposit the active chalcogenide material.

Those skilled in the art will appreciate that the methods and designs described above have additional applications and that the relevant applications are not limited to those specifically recited above. Also, the present invention may be embodied in other specific forms without departing from the essential characteristics as described herein. The embodiments described above are to be considered in all respects as illustrative only and not restrictive in any manner.

I claim:

1. A method of forming a chalcogenide material comprising:
heating a condensed-phase source material to a first temperature, said source material comprising a chalcogen element, said heating producing a vapor, said vapor comprising said chalcogen element; and
condensing said vapor on a deposition surface at a second temperature to form a product, said product comprising said chalcogen element.

2. The method of claim 1, wherein said condensed-phase source material is a solid-phase source material.

3. The method of claim 2, wherein said first temperature is a temperature below the melting temperature of said solid-phase source material.

4. The method of claim 1, wherein said condensed-phase source material comprises a phase-change material.

5. The method of claim 1, wherein said condensed phase source material comprises an electrical switching material.

6. The method of claim 1, wherein said condensed phase source material further comprises a first element.

7. The method of claim 6, wherein said first element is a column III element.

8. The method of claim 7, wherein said column III element is Ga or In.

9. The method of claim 6 wherein said first element is a column IV element.

10. The method of claim 9, wherein said column IV element is Ge or Si.

11. The method of claim 6, wherein said first element is a column V element.

12. The method of claim 11, wherein said column V element is Sb or As.

13. The method of claim 6, wherein said product comprises said first element.

14. The method of claim 13, wherein the atomic concentration of said chalcogen element in said product is between 70% and 130% of the atomic concentration of said chalcogen element in said source material.

15. The method of claim 14, wherein the atomic concentration of said first element in said product is between 70% and 130% of the atomic concentration of said first element in said source material.

16. The method of claim 13, wherein the atomic concentration of said chalcogen element in said product is between 80% and 120% of the atomic concentration of said chalcogen element in said source material.

17. The method of claim 16, wherein the atomic concentration of said first element in said product is between 80% and 120% of the atomic concentration of said first element in said source material.

18. The method of claim 13, wherein the atomic concentration of said chalcogen element in said product is between 90% and 110% of the atomic concentration of said chalcogen element in said source material.

19. The method of claim 18, wherein the atomic concentration of said first element in said product is between 90% and 110% of the atomic concentration of said first element in said source material.

20. The method of claim 13, wherein the atomic concentration of said chalcogen element in said product is between 95% and 105% of the atomic concentration of said chalcogen element in said source material.

21. The method of claim 20, wherein the atomic concentration of said first element in said product is between 95% and 105% of the atomic concentration of said first element in said source material.

22. The method of claim 6, wherein said condensed phase source material further comprises a second element.

23. The method of claim 22, wherein said first element is a column IV element and said second element is a column V element.

24. The method of claim 23, wherein said column IV element is Si or Ge and said column V element is Sb or As.

25. The method of claim 22, wherein said first element is a column III element and said second element is a column V element.

26. The method of claim 25, wherein said column III element is Ga or In and said column V element is Sb or As.

27. The method of claim 22, wherein said product further comprises said first element and said second element.

28. The method of claim 27, wherein the atomic concentration of said chalcogen element in said product is between 70% and 130% of the atomic concentration of said chalcogen element in said source material, the atomic concentration of said first element in said product is between 70% and 130% of the atomic concentration of said first element in said source material, and the atomic concentration of said second element in said product is between 70% and 130% of the atomic concentration of said second element in said source material.

29. The method of claim 27, wherein the atomic concentration of said chalcogen element in said product is between 80% and 120% of the atomic concentration of said chalcogen element in said source material, the atomic concentration of said first element in said product is between 80% and 120% of the atomic concentration of said first element in said source material, and the atomic concentration of said second element in said product is between 80% and 120% of the atomic concentration of said second element in said source material.

30. The method of claim 27, wherein the atomic concentration of said chalcogen element in said product is between 90% and 110% of the atomic concentration of said chalcogen element in said source material, the atomic concentration of said first element in said product is between 90% and 110% of the atomic concentration of said first element in said source material, and the atomic concentration of said second element in said product is between 90% and 110% of the atomic concentration of said second element in said source material.

31. The method of claim 27, wherein the atomic concentration of said chalcogen element in said product is between 95% and 105% of the atomic concentration of said chalcogen element in said source material, the atomic concentration of said first element in said product is between 95% and 105% of the atomic concentration of said first element in said source material, and the atomic concentration of said second element in said product is between 95% and 105% of the atomic concentration of said second element in said source material.

32. The method of claim 1, wherein said condensed phase source material is substantially free of carbon.

33. The method of claim 1, wherein said condensed phase source material is substantially free of nitrogen and hydrogen.

34. The method of claim 1, wherein said condensed phase source material consists essentially of said chalcogen element.

35. The method of claim 1, wherein said vapor is produced in a non-ionizing environment.

36. The method of claim 1, wherein said vapor is produced in a plasma-free environment.

37. The method of claim 1, wherein said vapor is produced by sublimation of said condensed phase source material.

38. The method of claim 1, wherein said vapor is produced by evaporation of said condensed phase source material.

39. The method of claim 1, wherein said product is formed in a non-ionizing environment.

40. The method of claim 1, wherein said product is formed in a plasma-free environment.

41. The method of claim 1, wherein said heating is accomplished by a process selected from the group consisting of resistive heating, lamp heating, and laser heating.

42. The method of claim 1, wherein the atomic concentration of said chalcogen element in said product is between 70% and 130% of the atomic concentration of said chalcogen element in said condensed phase source material.

43. The method of claim 1, wherein the atomic concentration of said chalcogen element in said product is between 80% and 120% of the atomic concentration of said chalcogen element in said condensed phase source material.

44. The method of claim 1, wherein the atomic concentration of said chalcogen element in said product is between 90% and 110% of the atomic concentration of said chalcogen element in said condensed phase source material.

45. The method of claim 1, wherein the atomic concentration of said chalcogen element in said product is between 95% and 105% of the atomic concentration of said chalcogen element in said condensed phase source material.

46. The method of claim 1, wherein said product consists essentially of the elements of said source material.

47. The method of claim 1, wherein said product forms in an amorphous phase.

48. The method of claim 1, wherein said product comprises a phase-change material.

49. The method of claim 1, wherein said product comprises an electrical switching material

50. The method of claim 1, wherein said second temperature is less than said first temperature.

51. The method of claim 1, wherein said second temperature is less than the melting temperature of said product.

52. The method of claim 1, wherein said second temperature is less than the glass transition temperature of said product.

53. The method of claim 1, wherein said deposition surface is remote from said source material.

54. The method of claim 1, wherein said deposition surface includes a feature, said product forming in said feature.

55. The method of claim 54, wherein said feature is an opening, trench, groove, hole, recess, via, edge or step.

56. The method of claim 54, wherein the cross-sectional shape of said feature includes a portion that is round, curved, elliptical, bent, or rectilinear.

57. The method of claim 54, wherein said feature has an aspect ratio between 0.25:1 and 5:1.

58. The method of claim 57, wherein said product conformally lines said feature.

59. The method of claim 57, wherein said product conformally fills said feature.

60. The method of claim 54, wherein said feature has an aspect ratio of at least 1:1.

61. The method of claim 54, wherein said feature has an aspect ratio of at least 2:1.

62. The method of claim 54, wherein said feature has an aspect ratio at least 3:1.

63. The method of claim 54, wherein said product conformally lines said feature.

64. The method of claim 54, wherein said product conformally fills said feature.

65. The method of claim 1, further comprising:
providing a second condensed phase source material, said second condensed phase source material including a first element; and
heating said second condensed phase source material to form a second vapor, said second vapor comprising said first element, said product being formed upon co-condensing said second vapor with said vapor formed from said condensed phase source material comprising a chalcogen element, said producing including said first element and said chalcogen element.

66. The method of claim 65, wherein said chalcogen element is Te or Se and said first element is In, Ge or Sb.
